(19) United States
(12) Patent Application Publication
(10) Pub. No.: US 2025/0201599 A1
(43) Pub. Date: Jun. 19, 2025

(54) EQUIPMENT FRONT-END MODULE AND METHOD FOR CONTROLLING HUMIDITY IN EQUIPMENT FRONT-END MODULE

(71) Applicant: SEMES CO., LTD., Chungcheongnam-do (KR)

(72) Inventor: Dukhyun SON, Chungcheongnam-do (KR)

(21) Appl. No.: 18/973,362

(22) Filed: Dec. 9, 2024

(30) Foreign Application Priority Data
Dec. 15, 2023 (KR) 10-2023-0183359

(51) Int. Cl. H01L 21/67; F24F 7/003; F24F 11/00; F24F 11/77; F24F 110/20; F24F 110/40; G05D 7/06

(52) U.S. Cl. CPC H01L 21/67201; F24F 7/003; F24F 11/0001; F24F 11/77; G05D 7/0676; F24F 2110/20; F24F 2110/40

(57) ABSTRACT

An equipment front-end module according to an aspect of the present invention includes: a load port; a transfer frame; a buffer unit; a fan filter unit; a gas supply unit; a differential pressure sensor installed on a portion of the transfer frame and configured to measure a differential pressure, which is a value obtained by subtracting an external pressure from an internal pressure of the transfer frame; a humidity sensor installed on a portion of the transfer frame and configured to measure humidity inside the transfer frame; and a control unit configured to control a rotation speed of the fan filter unit and a flow rate of gas supplied into the transfer frame through the gas supply unit, based on information received from the humidity sensor and the differential pressure sensor.

### CROSS-REFERENCE TO RELATED APPLICATION(S)

This application claims the benefit under 35 USC § 119 (a) of Korean Patent Application No. 10-2023-0183359, filed on Dec. 15, 2023, in the Korean Intellectual Property Office, the entire disclosure of which is incorporated herein by reference for all purposes.

### BACKGROUND

### 1. Field

The present invention relates to an equipment front-end module (EFEM) that constitutes a part of a semiconductor manufacturing facility, and more specifically, to an EFEM with a configuration that allows for the control of internal humidity and a method for controlling humidity within the EFEM.

### 2. Description of Related Art

Among processes for manufacturing semiconductor devices, the etching process, ion implantation process, thin-film deposition process, and other processes treat a substrate in a vacuum atmosphere. These processes are performed in one or more process units composed of chambers that can maintain a vacuum. A substrate to be treated may be stored in a cassette and transferred to the process unit through an equipment front-end module (EFEM). The equipment front-end module acts as an interface module connecting between the cassette containing the substrate and the process unit, and it includes a load port module that accommodates the cassette, a transfer frame configured to transfer the substrate within the cassette accommodated in the load port module, and a buffer unit that can store the substrate transferred by the transfer frame. Substrates that are being transferred or stored within the equipment front-end module may develop particles on their surface or become contaminated due to moisture infiltrating from outside. Therefore, the humidity inside the equipment front-end module must be kept below a reference value. However, due to various environmental factors or issues with the equipment, the internal humidity may increase. For example, when the load port module is opened to transfer a substrate, the sudden change in pressure inside the equipment front-end module may cause an increase in humidity. If the humidity increases significantly, a large number of particles may form on the substrate, or contamination due to oxidation may occur.

### SUMMARY

The present invention has been devised to address various problems including the aforementioned problems of the related art and an object of the present invention is to provide an equipment front-end module (EFEM) equipped with a humidity control device capable of efficiently controlling humidity within the equipment front-end module and maintaining a clean condition of a substrate, as well as a method for controlling humidity within the equipment front-end module using the humidity control device. However, this object is merely illustrative, and the scope of the present invention is not limited thereto.

According to an aspect of the present invention, there is provided an equipment front-end module including: a load port on which a carriage containing a substrate is seated; a transfer frame including a space where a substrate contained in the load port is brought in and transferred; a buffer unit including an open face formed on a surface facing the transfer frame; a fan filter unit, with one end connected to the other end of a circulation line that is connected to an exhaust port of the buffer unit, configured to introduce gas supplied from the circulation line into the transfer frame; a gas supply unit configured to supply gas into the transfer frame; a differential pressure sensor installed on a portion of the transfer frame and configured to measure a differential pressure, which is a value obtained by subtracting an external pressure from an internal pressure of the transfer frame; a humidity sensor installed on a portion of the transfer frame and configured to measure humidity inside the transfer frame; and a control unit configured to control a rotation speed of the fan filter unit and a flow rate of gas supplied into the transfer frame through the gas supply unit, based on information received from the humidity sensor and the differential pressure sensor.

The equipment front-end module may include a fan filter unit control unit configured to receive a fan filter unit control signal transmitted from the control unit and control the rotation speed of the fan filter unit according to the fan filter unit control signal.

The equipment front-end module may include a mass flow controller configured to receive a gas flow rate control signal transmitted from the control unit and control a flow rate of gas flowing through the gas supply unit according to the gas flow rate control signal.

The gas supplied into the transfer frame may flow into a buffer space through the open face and may be discharged through an exhaust port of the buffer unit.

The control unit may determine whether differential pressure information received from the differential pressure sensor meets preset criteria when it is determined that humidity information received from the humidity sensor deviates from the preset criteria.

The control unit may perform control to simultaneously increase the rotation speed of the fan filter unit and the flow rate of gas flowing through the gas supply unit when it is determined that the differential pressure information does not meet the preset criteria.

The control unit may generate a fan filter unit control signal and transmit it to a fan filter unit control unit configured to control the rotation speed of the fan filter unit, while simultaneously generating a gas flow rate control signal and transmitting it to a mass flow controller configured to control the flow rate of gas flowing through the gas supply unit.

The fan filter unit control signal and the gas flow rate control signal may be generated as values proportional to the differential pressure measured by the differential pressure sensor.

The gas supply unit may include a gas nozzle configured to discharge gas into an internal space of the transfer frame, a gas supply line connected to the gas nozzle, and a mass flow controller configured to receive a gas flow rate control signal from the control unit and control a flow rate of gas flowing through the gas supply line according to the received gas flow rate control signal.

According to an aspect of the present invention, there is provided a method for controlling humidity in an equipment front-end module, which comprises a transfer frame including a space where a substrate contained in a load port is brought in and transferred, and a buffer unit with an open face formed on a surface facing the transfer frame.

According to one embodiment, the method for controlling humidity in the equipment front-end module includes: measuring a differential pressure, which is a value obtained by subtracting an external pressure from an internal pressure of the transfer frame; comparing the measured differential pressure with a reference value according to preset criteria; and changing the internal pressure of the transfer frame by changing a flow rate of gas supplied into the transfer frame through a gas supply unit and changing a rotation speed of a fan filter unit configured to supply gas into the transfer frame, when it is determined that the measured differential pressure does not meet the preset criteria.

The method may further include, before measuring the differential pressure, measuring humidity inside the transfer frame; comparing the measured humidity with a reference value according to preset criteria; and determining that the measured humidity does not meet the preset criteria.

The changing of the flow rate of the supplied gas and the changing of a speed of supply of the gas may be performed simultaneously.

In the comparing of the measured differential pressure with the reference value according to the preset criteria, the preset criteria may indicate whether the measured differential pressure has a value less than or greater than the reference value.

The changing of the flow rate of the supplied gas may include increasing the flow rate of the supplied gas, and changing of a speed of supply of the gas may include increasing the speed of supply of the gas supplied.

The method may include, before measuring the differential pressure, opening the load port to decrease the internal pressure of the transfer frame. In this case, the changing of the flow rate of the supplied gas may be to increase the flow rate of the supplied gas and changing of a speed of supply of the gas may be to increase the speed of supply of the supplied gas.

The method may further include, before measuring the differential pressure, closing the load port to increase the internal pressure of the transfer frame. In this case, the changing of the flow rate of the supplied gas may be to reduce the flow rate of the supplied gas, and changing of a speed of supply of the gas may be to reduce the speed of supply of the supplied gas.

The method may comprise a step in which the gas supplied into the transfer frame flows into a buffer space through the open face and is discharged through an exhaust port of the buffer unit.

According to an aspect of the present invention, there is provided An equipment front-end module including: a load port on which a carriage containing a substrate is seated; a transfer frame including a space where a substrate contained in the load port is brought in and transferred; a buffer unit including an open face formed on a surface facing the transfer frame and a space where the substrate is temporarily stored; a fan filter unit, with one end connected to the other end of a circulation line that is connected to an exhaust port of the buffer unit, configured to introduce gas supplied from the circulation line into the transfer frame; a gas supply unit configured to supply gas into the transfer frame; a differential pressure sensor configured to measure a pressure difference between the inside and outside of the transfer frame; a humidity sensor configured to measure humidity inside the transfer frame; and a control unit configured to control a rotation speed of the fan filter unit and a flow rate of gas supplied through the gas supply unit, based on information received from the humidity sensor and the differential pressure sensor, wherein the control unit is configured to determine whether differential pressure information received from the differential pressure sensor meets preset criteria when it is determined that humidity information received from the humidity sensor deviates from the preset criteria, and to control the rotation speed of the fan filter unit and the flow rate of gas flowing through the gas supply unit to be changed simultaneously when it is determined that the differential pressure information does not meet the preset criteria.

### BRIEF DESCRIPTION OF THE DRAWINGS

FIG. 1 is an illustrative drawing representing a semiconductor manufacturing facility according to one embodiment of the present invention.

FIG. 2 is a schematic view illustrating the transfer frame and buffer unit shown in FIG. 1.

FIG. 3 is a diagram illustrating a method for generating a fan filter unit control signal and a gas flow rate control signal.

FIGS. 4, 5, and 6 are process flowcharts illustrating step-by-step a method for controlling humidity and differential pressure according to one embodiment of the present invention.

FIG. 7 shows the experimental results measuring the humidity according to the differential pressure control of the equipment front-end module.

Throughout the drawings and the detailed description, unless otherwise described, the same drawing reference numerals will be understood to refer to the same elements, features, and structures. The relative size and depiction of these elements may be exaggerated for clarity, illustration, and convenience.

### DETAILED DESCRIPTION

Hereinafter, various preferred embodiments of the present invention will be described in detail with reference to the accompanying drawings.

The invention may, however, be embodied in many different forms and should not be construed as being limited to the embodiments set forth herein; rather, these embodiments are provided so that this disclosure will be thorough and complete, and will fully convey the concept of the invention to one of ordinary skill in the art. Moreover, in the drawing figures, the thickness or dimensions of layers are exaggerated for clarity and convenience of explanation.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, components, and/or groups thereof, but do not preclude the presence or addition of one or more other features, integers, steps, operations, elements, components, and/or groups thereof.

Embodiments of the invention are described herein with reference to drawings that are schematic illustrations of idealized embodiments of the invention. As such, variations from the shapes of the drawings as a result, for example, of manufacturing techniques and/or tolerances, are to be expected. Thus, embodiments of the inventive concept should not be construed as limited to the particular shapes of regions illustrated herein but are to include deviations in shapes that result, for example, from manufacturing.

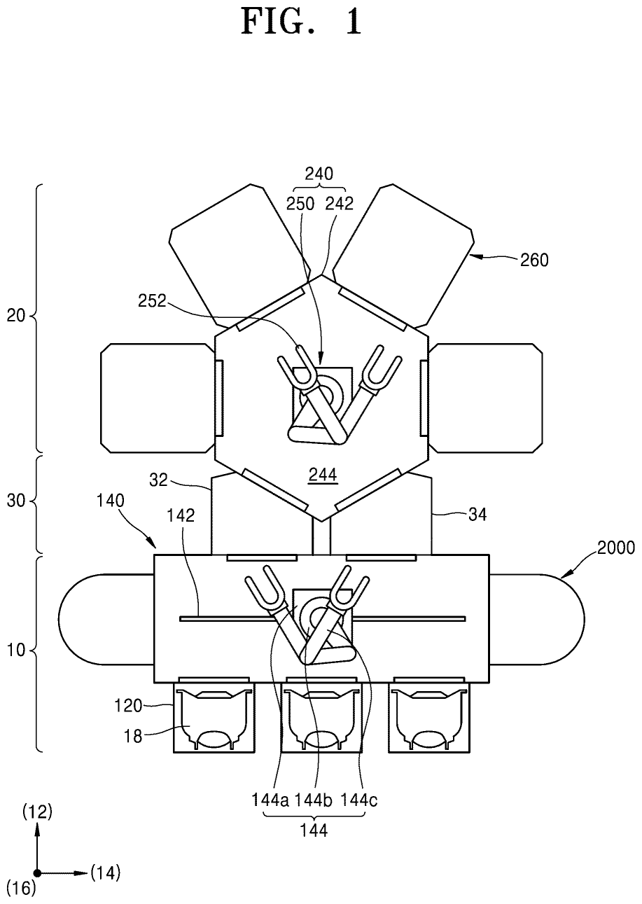

FIG. 1 is an illustrative drawing representing a semiconductor manufacturing facility 1. Referring to FIG. 1, a semiconductor manufacturing facility 1 includes an equipment front-end module (EFEM) 10, a process module 20, and a loading module 30.

The EFEM 10 includes a load port 120, a transfer frame 140, and a buffer unit 2000. The load port 120, the transfer frame 140, and the process module 20 are arranged sequentially in a line. Hereinafter, the direction in which the load port 120, the transfer frame 140, the loading module 30, and the process module 20 are arranged is referred to as a first direction 12. When viewed from above, a direction perpendicular to the first direction 12 is referred to as a second direction 14, and a direction perpendicular to the plane formed by the first direction 12 and the second direction 14 is referred to as a third direction 16.

A carrier 18 containing a plurality of substrates is seated on the load port 120. A plurality of load ports 120 are provided and they are arranged in a line along the second direction 14. In FIG. 1, three load ports 120 are shown. However, the number of load ports 120 may increase or decrease depending on conditions such as the process efficiency and footprint of the process module 20. The carrier 18 may have slots (not shown) provided to support the edges of the substrates. A plurality of slots are provided along the third direction 16, and the substrates are positioned within the carrier 18 such that they are stacked with spaces between them along the third direction 16. The carrier 18 may be a front opening unified pod (FOUP).

The transfer frame 140 transfers the substrates between the carrier 18 seated on the load port 120, the buffer unit 2000, and the loading module 30. The transfer frame 140 is provided with an index rail 142 and an index robot 144. The index rail 142 is provided such that its length direction is parallel to the second direction 14. The index robot 144 is installed on the index rail 142 and moves linearly along the index rail 142 in the second direction 14. The index robot 144 consists of a base 144a, a body 144b, and an index arm 144c. The base 144a is installed to be movable along the index rail 142. The body 144b is coupled to the base 144a. The body 144b is provided to be movable along the third direction 16 on the base 144a.

Additionally, the body 144b is provided to be rotatable on the base 144a. The index arm 144c is joined to the body 144b and is provided to be movable forward and backward relative to the body 144b. A plurality of index arms 144c are provided to be driven individually. The index arms 144c are arranged in a stacked configuration, spaced apart from each other along the third direction 16. Some of the index arms 144c are used when the substrates are transferred from the process module 20 to the carrier 18, while some others are used when the substrates are transferred from the carrier 18 to the process module 20. This structure prevents particles generated from substrates before treatment process from adhering to substrates after the treatment process during the transfer of the substrates in and out by the index robot 144.

The loading module 30 is disposed between the transfer frame 140 and a transfer chamber 242. The loading module 30 provides a space in which the substrate resides before being conveyed between the transfer chamber 242 and the transfer frame 140. The loading module 30 includes a load lock chamber 32 and an unload lock chamber 34. The load lock chamber 32 and the unload lock chamber 34 are each configured to allow their interiors to switch between a vacuum atmosphere and an atmospheric pressure atmosphere.

The load lock chamber 32 temporarily holds the substrates that are transferred from the equipment front-end module 10 to the process module 20. When the substrate is transferred into the load lock chamber 32, the internal space of the load lock chamber 32 is sealed off from both the equipment front-end module 10 and the process module 20. Thereafter, the inner space of the load lock chamber 32 is switched from an atmospheric pressure atmosphere to a vacuum atmosphere, and it is opened to the process module 20 while remaining sealed off from the equipment front-end module 10.

The unload lock chamber 34 temporarily holds the substrates that are transferred from the process module 20 to the equipment front-end module 10. When the substrate is transferred into the unload lock chamber 34, the inner space of the unload lock chamber 34 is sealed off from both the equipment front-end module 10 and the process module 20. Thereafter, the inner space of the unload lock chamber 34 is switched from an atmospheric pressure atmosphere to a vacuum atmosphere, and it is opened to the equipment front-end module 10 while remaining sealed off from the process module 20.

The process module 200 includes a transfer chamber 242 and a plurality of process units 260.

The transfer chamber 242 transfers a substrate W between the load lock chamber 32, the unload lock chamber 34, and the plurality of process units 260. The transfer chamber 242 may have a hexagonal shape when viewed from above. Alternatively, the transfer chamber 242 may have a rectangular or pentagonal shape. The load lock chamber 32, the unload lock chamber 34, and the plurality of process units 260 are located around the transfer chamber 242. A transfer robot 250 is provided in the transfer chamber 242. The transfer robot 250 may be located at the center of the transfer chamber 242. The transfer robot 250 may have a plurality of hands 252 that are movable in the horizontal and vertical directions and capable of moving forward, backward, or rotating on the horizontal plane. Each of the hands 252 is operable independently, and substrates W may be horizontally seated on the hands 252.

A gas processing apparatus provided in each of the process units 260 performs an etching or deposition process on a substrate. According to one embodiment, each gas processing apparatus may perform a different gas processing operation. A first apparatus may perform a first process of supplying a first gas, and a second apparatus may perform a second process of supplying a second gas. The first gas may include fluorine (F), chlorine (Cl), or bromine (Br), and the second gas may include ammonia (NH₃).

Hereinafter, the transfer frame 140 and buffer unit 2000 provided in the equipment front-end module 10 will be described in detail with reference to the drawings.

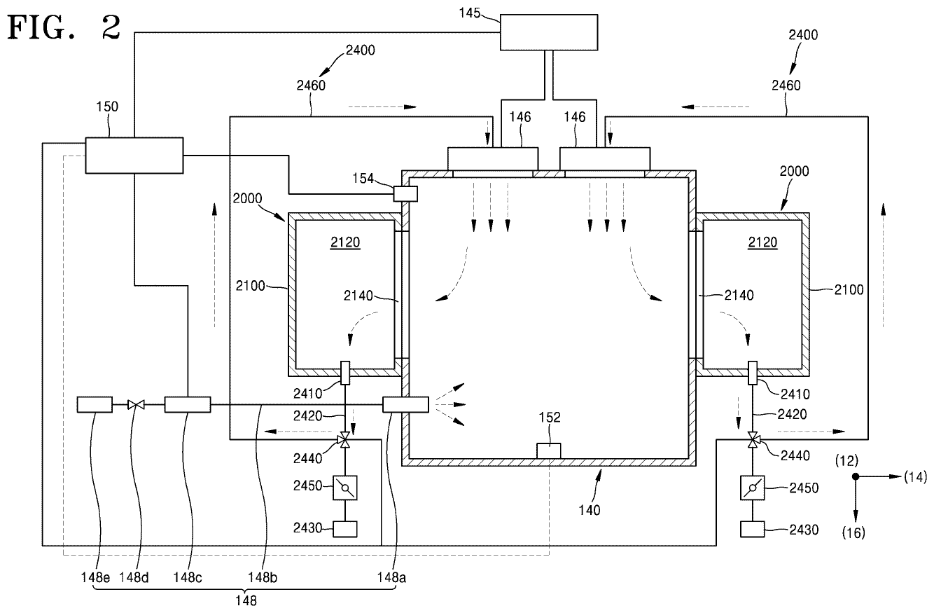

FIG. 2 is a schematic view illustrating the transfer frame and buffer unit shown in FIG. 1.

Referring to FIG. 2, a fan filter unit (FFU) 146 and an FFU control unit 145 are installed in the transfer frame 140. The FFU 146 may be installed on the ceiling surface of the transfer frame 140. The FFU 146 introduces gas supplied from a circulation line 2460, described below, into the inner space of the transfer frame 140 using a rotating fan. At this time, the FFU 146 may form a downward airflow in the inner space of the transfer frame 140. The operation of the FFU 146 is controlled by the FFU control unit 145. By controlling the rotation speed of the FFU 146 (i.e., the rotation speed of the fan), the speed of the gas introduced into the transfer frame 140 may be controlled.

The transfer frame 140 is provided with a gas supply unit 148. The gas supply unit 148 is installed on the sidewall of the transfer frame 140 and may be positioned so as not to affect the buffer unit 2000. The gas supply unit 148 includes a gas nozzle 148a, a gas supply line 148b, a mass flow controller (MFC) 148c, and a gas valve 148d designed to shut off the supply of gas from the gas source 148e.

The gas nozzle 148a discharges gas into the inner space of the transfer frame 140. The gas nozzle 148a may be installed on the sidewall of the transfer frame 140. The gas supply line 148b is connected to the gas nozzle 148a. The gas supply line 148b is connected to the MFC 148c and supplied with a constant amount of gas from the gas source 148e. The MFC 148c may receive a gas flow rate control signal from the control unit 150 and, according to that signal, control the flow rate of gas flowing through the gas supply line 148b. The gas discharged from the gas nozzle 148a may include, for example, nitrogen gas (N₂ gas).

The transfer frame 140 is equipped with a humidity sensor 152 to measure the humidity inside the transfer frame 140, and a differential pressure sensor 154 to measure the pressure difference (referred to as differential pressure) between the inside and outside of the transfer frame 140. Here, the differential pressure is defined as the value obtained by subtracting the external pressure (e.g., atmospheric pressure) from the internal pressure of the transfer frame 140. Therefore, a positive differential pressure means that the internal pressure of the transfer frame 140 is maintained higher than the external pressure.

The humidity sensor 152 and the differential pressure sensor 154 transmit the measured humidity information and the measured differential pressure information to the control unit 150 in real time. The control unit 150 may receive the measured information and, based on this information, perform control to maintain the humidity and differential pressure inside the transfer frame 140 at predetermined reference values.

Specifically, the control unit 150 compares the humidity information received from the humidity sensor 152 with the predetermined humidity reference value to determine the subsequent operation to be performed. For example, if the humidity measured by the humidity sensor 152 is higher than the reference value, an operation is performed to check if there is a problem with the differential pressure in the transfer frame 140.

To this end, the control unit 150 performs a step of comparing the differential pressure information received from the differential pressure sensor 154 with the preset reference value of a differential pressure. If the comparison result shows that the measured differential pressure is lower than the reference value (for example, either a positive value lower than the reference value or a negative value), the control unit generates an FFU control signal and a gas flow rate control signal to restore the differential pressure to the reference value.

The generated FFU control signal is transmitted to the FFU control unit 145, and upon receiving this signal, the FFU control unit 145 performs control to increase the rotation speed of the FFU 146.

The generated gas flow rate control signal is transmitted to the MFC 148c, and upon receiving this signal, the MFC 148c performs control to increase the flow rate of gas supplied to the transfer frame 140.

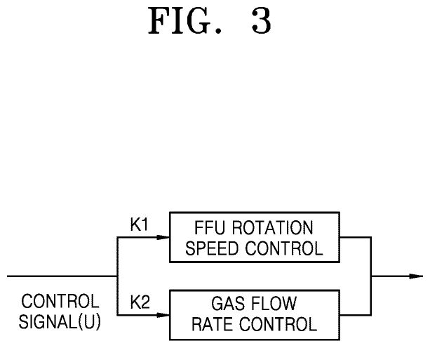

The FFU control signal and gas flow rate control signal may be generated as functions of the differential pressure in the transfer frame 140. For example, as shown in FIG. 3, the FFU control signal may be set as the value obtained by multiplying the difference between the actual differential pressure in the transfer frame 140, as measured by the differential pressure sensor 154, and the reference value, by a control constant K1. Additionally, the gas flow rate control signal may be set as the value obtained by multiplying the difference between the actual differential pressure in the transfer frame 140, as measured by the differential pressure sensor 154, and the reference value, by a control constant K2.

In this way, the control unit 150 may control the rotation speed of the FFU 146 and the flow rate of gas supplied into the transfer frame 140 to ensure that the differential pressure of the transfer frame 140 reaches the reference value as quickly as possible.

The control unit 150 may perform control to increase or decrease the rotation speed of the FFU and the gas flow rate through the mass gas controller based on changes in differential pressure received from the differential pressure sensor, in order to quickly restore the sudden pressure changes inside the transfer frame 140 caused by the opening and closing of the load port 120.

The buffer unit 2000 temporarily stores the substrates processed in the process module 20. The buffer unit 2000 removes residual process byproducts from the surface of the substrates. The removal of process byproducts in the buffer unit 2000 is performed by raising or lowering the pressure in the buffer unit 2000. A plurality of buffer units 2000 may be provided. For example, two buffer units 2000 may be provided. The two buffer units 2000 may be placed on either side of the transfer frame 140, facing each other with the transfer frame 140 therebetween. Alternatively, only one buffer unit 2000 may be provided on one side of the transfer frame 140.

Specifically, the buffer unit 2000 includes a housing 2100 and an exhaust circulation unit 2400 formed on one side of the housing 2100 to exhaust gases from the interior of the housing 2100. The buffer unit 2000 also further includes a substrate support unit formed inside the housing 2100 to store the substrates.

The housing 2100 is provided in a tubular shape with a buffer space 2120 inside. The housing 2100 has a length in the direction of the third direction 16. The buffer space 2120 is provided as a space capable of accommodating a plurality of substrates. The housing 2100 has an open face 2140, which faces the transfer frame 140. The open face 2140 functions as an entrance through which substrates are transferred between the transfer frame 140 and the buffer space 2120. Through the open face 2140, gas is supplied from the inner space of the transfer frame 140 into the buffer space 2120.

The exhaust circulation unit 2400 may exhaust the atmosphere of the buffer space 2120. The exhaust circulation unit 2400 may include an exhaust port 2410, an exhaust line 2420, an exhaust member 2430, a valve 2440, a flow rate control valve 2450, and a circulation line 2460.

The exhaust port 2410 functions as the passage through which the atmosphere of the buffer space 2120 is exhausted. Particles and fumes removed from the substrates are exhausted through the exhaust port 2410. The exhaust port 2410 may be located at the center of the bottom plate of the housing 2100. The exhaust port 2410 may be provided as a hole through which the atmosphere of the buffer space 2120 is exhausted.

The exhaust port 2410 is connected to the exhaust line 2420. The exhaust line 2420 connects the exhaust port 2410 to the exhaust member 2430. The exhaust line 2420 transmits the suction pressure from the exhaust member 2430 to the exhaust port 2410. Through this, the suction pressure is provided to the buffer space 2120, which depressurizes the buffer space 2120, allowing particles inside the buffer space 2120 or particles attached to the substrates stored in the buffer space 2120 to be exhausted. The exhaust member 2430 may include a depressurizing member, such as a vacuum pump.

The valve 2440 is installed at the junction of the exhaust line 2420 and the circulation line 2460. The valve 2440 may, for example, be a three-way valve that controls the flow of gas in three directions. The valve 2440 may selectively open or close the exhaust line 2420 and the circulation line 2460 under the control of the control unit 150.

The flow rate control valve 2450 may be a throttle valve. The flow rate control valve 2450 is installed between the valve 2440 and the exhaust member 2430. The flow rate control valve 2450 controls the internal flow rate of the buffer space 2120 by adjusting the opening/closing rate of the exhaust line 2420. This allows the removal of particles, such as fumes, from the surface of the substrate.

The circulation line 2460 branches from the exhaust line 2420. One end of the circulation line 2460 is connected to the valve 2440, and the other end is connected to the FFU 146 of the transfer frame 140. The control unit 150 may control the exhaust circulation unit 2400 to operate in either an exhaust mode, in which the buffer space 2120 is exhausted through the exhaust line 2420, or a circulation mode, in which gas is supplied to the inner space of the transfer frame 140 through the circulation line 2460. The control unit 150 controls the valve 2440 to ensure that only one of the exhaust mode or circulation mode is maintained. The selection between the circulation mode and the exhaust mode may vary depending on the type of gas used to treat the substrate before the substrate is stored in the buffer space 2120. According to one embodiment, the circulation mode may be maintained for a substrate subjected to the first process, while the exhaust mode may be maintained for a substrate subjected to the second process.

When the exhaust mode is selected by the control unit 150, the control unit 150 controls the valve 2440 to open the exhaust line 2420 and close the circulation line 2460. At this time, the flow rate control valve 2450 may adjust the opening/closing rate of the exhaust line 2420 to control the flow speed inside the buffer space 2120. By controlling the flow speed, particles such as fumes on the substrate surface may be removed.

When the circulation mode is selected by the control unit 150, the control unit 150 controls the valve 2440 to close the exhaust line 2420 and open the circulation line 2460. One end of the circulation line 2460 is connected to the exhaust port 2410, and the other end is connected to the FFU 146. Therefore, the gas passing through the exhaust port 2410 flows into the circulation line 2460 through the valve 2440, and via the circulation line 2460, the gas is supplied to the inner space of the transfer frame 140 by the FFU 146. The gas entering the inner space of the transfer frame 140 flows into the buffer space 2120 through the open face 2140. The gas that flows into the buffer space 2120 then re-enters the circulation line 2460 through the exhaust port 2410 and flows back to the FFU 146, thereby establishing the circulation mode.

The control unit 150 may select between the exhaust mode and the circulation mode based on the type of process fluid used in the treatment process immediately before the substrate is stored in the buffer unit 2000. The control unit 150 may select between the exhaust mode and the circulation mode depending on the type of residual process byproducts remaining on the substrate. For example, if polymer particles remain on the substrate, the control unit 150 may select the exhaust mode. In another example, if the process fluid used in the substrate treatment process includes fluorine (F), hydrogen bromide (HBr), chlorine (Cl), or the like, the control unit 150 may select the exhaust mode. Alternatively, if the process fluid used in the treatment process is ammonia (NH₃), the control unit 150 may select the circulation mode.

When the substrate is transferred to the process module 20 using the transfer frame 140 for processing, or when the substrate is transferred to the buffer unit 2000 to store it in the buffer unit 2000, the internal pressure of the transfer frame 140 must always be maintained at a higher pressure than the external pressure. Additionally, in this process, to prevent particles from attaching to the substrate or a large amount of fumes from forming, the humidity inside the transfer frame 140 must be controlled to avoid sudden fluctuations and should always be kept constant.

To maintain a low level of humidity inside the transfer frame 140, it is necessary to manage the differential pressure to meet preset criteria. For example, by maintaining the differential pressure at a higher value than the reference value, external moisture can be effectively prevented from penetrating the inside of the transfer frame 140.

To manage the differential pressure, an operation of setting a reference value for the differential pressure and comparing between this reference value and the actual differential pressure measured by the differential pressure sensor 154 according to the preset criteria. If the comparison results show that the measured differential pressure meets the preset criteria, the current state is maintained. However, if it is determined that the preset criteria are not met, control may be performed to make the differential pressure meet the predetermined criteria.

If the humidity inside the transfer frame 140 rises above the reference value, there is a possibility that an issue has occurred with the differential pressure management in the transfer frame 140. Therefore, appropriate control of the differential pressure must be carried out to normalize the humidity by reducing it back to below the reference value.

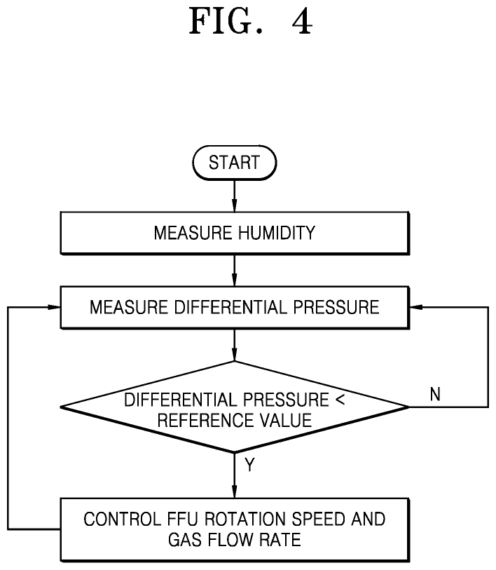

FIG. 4 is a flowchart illustrating the steps for controlling humidity and differential pressure according to one embodiment of the present invention. Below, a method for controlling the humidity inside the transfer frame 140 will be described with reference to FIGS. 2 and 4.

When the circulation mode is selected by the control unit 150, the exhaust gas passing through the exhaust port 2410 flows into the circulation line 2460 through the valve 2440, and is supplied to the inner space of the transfer frame 140 via the circulation line 2460, and then flows into the buffer space 2120.

A step is performed to measure the humidity using the humidity sensor 152. The humidity sensor 152 measures the humidity inside the transfer frame 140 in real time and transmits the measured humidity information to the control unit 150 in real time.

The control unit 150, which has received the measured humidity information, compares the received humidity information with the preset reference value and determines whether the received humidity information is greater than or equal to the reference value. For example, if it is determined that the measured humidity is lower than the reference value, the control unit continues humidity measurement without taking further action, as the humidity inside the transfer frame 140 is being maintained normally.

However, if the humidity measured by the humidity sensor 152 is greater than or equal to the reference value, the control unit 150 determines that there is a problem with the humidity control inside the transfer frame 140 and proceeds to a step to obtain differential pressure information. To this end, the control unit 150 performs a step of comparing the differential pressure information received from the differential pressure sensor 154 with the preset reference value.

If, as a result of the comparison, it is determined that the differential pressure measured by the differential pressure sensor 154 is below the reference value, the control unit 150 generates an FFU control signal to increase the rotation speed of the FFU 146 and transmits the signal to the FFU control unit 145. Simultaneously, the control unit 150 generates a gas flow rate control signal to increase the flow rate of gas flowing into the transfer frame 140 and transmits the signal to the MFC 148c. The FFU control unit 145 increases the rotation speed of the FFU 146 according to the received FFU control signal. Additionally, the MFC 148c, which has received the gas flow rate control signal, increases the flow rate of the gas flowing through the gas supply line 148b, thereby increasing the flow rate of gas supplied into the transfer frame 140.

Due to the increase in the rotation speed of the FFU 136 and the increased flow rate of gas flowing into the transfer frame 140, the internal pressure of the transfer frame 140 increases, leading to an increase in differential pressure. This increase in differential pressure prevents moisture from penetrating the inside of the transfer frame 140 from the outside.

If the humidity information measured by the humidity sensor 152 is significantly higher than the reference value, but the differential pressure measured by the differential pressure sensor 154 is determined to exceed the reference value, it may be concluded that there is an operational error in the humidity sensor 152 or another issue is preventing the humidity from being normally maintained, even though the differential pressure is maintained. In such a case, the entire transfer frame 140 system may be inspected.

According to the embodiment of the present invention, if the differential pressure of the transfer frame 140 is lower than the reference value, the internal pressure of the transfer frame 140 may be rapidly raised by increasing the rotation speed of the FFU 146 while simultaneously increasing the flow rate of gas supplied into the transfer frame 140. The longer the time that the differential pressure is maintained at a value lower than the reference value, the lower the effect of blocking moisture from penetrating the inside of the transfer frame 140 from the outside.

According to the embodiment of the present invention, increasing the flow rate of gas supplied into the transfer frame 140 while simultaneously increasing the rotation speed of the FFU may result in a faster increase in the speed at which gas is supplied into the transfer frame 140. Therefore, compared to conventional techniques that only increase the flow rate of gas supplied, the differential pressure may be raised more quickly. This rapid increase in differential pressure significantly reduces the possibility of moisture penetrating the inside of the transfer frame 140, which is advantageous for controlling humidity at a low level.

In another example, the humidity inside the transfer frame 140 may be affected by the opening and closing of the load port 120. For example, when opening the load port 120 to transfer a substrate to the process module 20 and inserting the cassette 18 containing the substrate, the internal pressure of the transfer frame 140 connected to the load port 120 may drop, allowing air from the outside to rapidly flow into the transfer frame 140. The air that rapidly flows into the transfer frame 140 may contain a high level of moisture. Therefore, it is necessary to restore the internal pressure of the transfer frame 140 to its original state as quickly as possible to prevent an increase in humidity inside the transfer frame 140 due to the introduction of moisture from the outside.

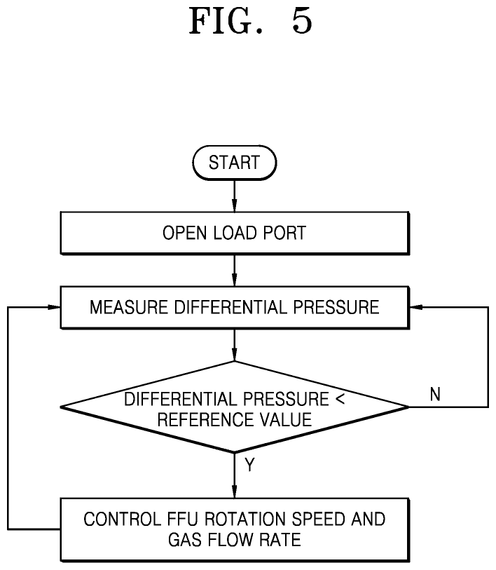

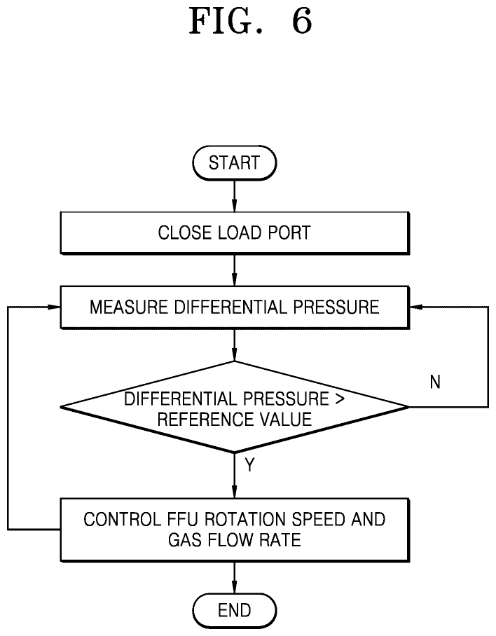

FIGS. 5 and 6 illustrate a method for controlling a differential pressure according to one embodiment of the present invention. Referring to FIGS. 1 and 5, the load port 120 is opened when the circulation mode is selected. Upon opening the load port, the pressure inside the transfer frame 140, which has been maintained higher than the external atmospheric pressure, decreases.

In this case, the differential pressure sensor 154, which measures the differential pressure of the transfer frame 140 in real time, measures the differential pressure and transmits the measured differential pressure information to the control unit 150. The control unit 150, which has received the differential pressure information, performs a step of comparing it with a preset reference value.

If, as a result of the comparison, the differential pressure measured by the differential pressure sensor 154 is determined to be lower than the reference value, the control unit 150 generates an FFU control signal to increase the rotation speed of the FFU 146 and transmits it to the FFU control unit 145. Simultaneously, the control unit 150 generates a gas flow rate control signal to increase the flow rate of gas flowing into the transfer frame 140 and transmits the signal to the MFC 148c. The FFU control unit 145 increases the rotation speed of the FFU 146 according to the received FFU control signal. Additionally, the MFC 148c, which has received the gas flow rate control signal, increases the flow rate of the gas flowing through the gas supply line 148b, thereby increasing the flow rate of gas supplied into the transfer frame 140.

Due to the increase in the rotation speed of the FFU and the increased flow rate of gas flowing into the transfer frame 140, the internal pressure of the transfer frame 140 rapidly increases, causing the differential pressure to rise and reach the reference value. This increase in differential pressure prevents moisture from penetrating the inside of the transfer frame 140 from the outside.

FIG. 6 illustrates a method for controlling a differential pressure after the previously opened load port is closed again.

Referring to FIGS. 1 and 6, the previously opened load port 120 is closed again. As the rotation speed of the FFU and the gas flow rate are maintained even after the load port is closed, the internal pressure of the transfer frame 140 continues to increase to a higher level. If the internal pressure of the transfer frame 140 becomes excessively high, it may cause instability in the equipment due to the large differential pressure. Therefore, it is necessary to reduce the differential pressure to an appropriate level.

The differential pressure sensor 154, which measures the differential pressure of the transfer frame 140 in real time, measures the differential pressure and transmits the measured differential pressure information to the control unit 150. The control unit 150, which has received the differential pressure information, performs a step of comparing it with a preset reference value.

If, as a result of the comparison, the differential pressure measured by the differential pressure sensor 154 is determined to exceed the reference value, the control unit 150 generates an FFU control signal to decrease the rotation speed of the FFU 146 and transmits it to the FFU control unit 145. Simultaneously, the control unit 150 generates a gas flow rate control signal to reduce the flow rate of gas flowing into the transfer frame 140 and sends it to the MFC 148c.

The FFU control unit 145 decreases the rotation speed of the FFU 146 according to the received FFU control signal. Additionally, the MFC 148c, which has received the gas flow rate control signal, decreases the flow rate of gas flowing through the gas supply line 148b, thereby reducing the flow rate of gas supplied into the transfer frame 140.

Due to the decrease in the rotation speed of the FFU and the reduced flow rate of gas flowing into the transfer frame 140, the internal pressure of the transfer frame 140 rapidly decreases, causing the differential pressure to decrease and reach the reference value.

According to the present embodiment, even if a rapid decrease in the internal pressure of the transfer frame occurs due to the opening of the load port, or a rapid increase in internal pressure occurs due to the closing of the load port, controlling simultaneously the fan unit's rotation speed and the gas supply flow rate allows the differential pressure, which deviates from the reference value, to be restored to the reference value as quickly as possible. This rapid restoration of the differential pressure means that the time for external moisture to penetrate the inside of the transfer frame is reduced, contributing to maintaining the appropriate humidity level inside the transfer frame.

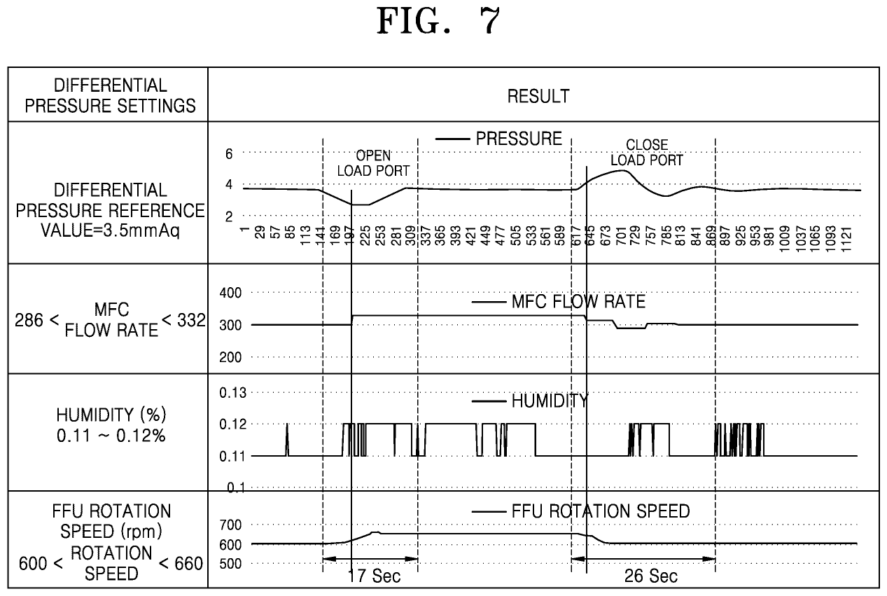

FIG. 7 shows the result of controlling the internal pressure of the transfer frame using the FFU and the MFC, according to the technical concept of the present invention.

The graph in FIG. 7, from top to bottom, shows the following in order: the change in differential pressure (in mmAq) of the transfer frame 140 over time (in increments of 0.1 seconds), the change in flow rate of nitrogen gas (in LPM) passing through the MFC 148c, the change in humidity inside the transfer frame 140 (in percentage), and the change in rotation speed of the FFU 146 (in rpm). The reference value for the differential pressure to control the FFU and the MFC is set to 3.5 mmAq.

Referring to FIG. 7, when the load port 120 is opened, the internal pressure of the transfer frame 140, which has been maintained higher than the external atmospheric pressure, drops rapidly. The differential pressure sensor 154 detects this change and measures the differential pressure. When the control unit 150 receives the real-time differential pressure measured by the differential pressure sensor 154 and determines that the differential pressure is lower than the reference value of 3.5 mmAq, the control unit 150 controls the FFU control unit 145 and the MFC 148c to increase the internal pressure of the transfer frame 140. As a result of the control, the rotation speed of the FFU 146 increases, and the flow rate of nitrogen gas supplied to the transfer frame 140 through the MFC 148c also increases. Consequently, the internal pressure of the transfer frame 140 rapidly increases, and the differential pressure quickly returns to the reference value.

When the load port 120 is closed again, the differential pressure begins to increase due to the rise in internal pressure of the transfer frame 140. When the control unit 150, which has received real-time differential pressure measurement from the differential pressure sensor 154, determines that the differential pressure exceeds the reference value of 3.5 mmAq, it controls the FFU control unit 145 and the MFC 148c to reduce the internal pressure of the transfer frame 140. As a result of this control, the rotation speed of the FFU 146 decreases, and the flow rate of nitrogen gas supplied to the transfer frame 140 through the MFC 148c also decreases. Consequently, the internal pressure of the transfer frame 140 rapidly decreases, and the differential pressure quickly returns to the reference value.

In this way, by simultaneously controlling the FFU 146 and the MFC 148c based on the differential pressure measured by the differential pressure sensor 154, it can be confirmed that the time required for the differential pressure inside the transfer frame 140, which has been changed due to the opening and closing of the load port 120, to return to the reference value is less than 30 seconds. In particular, throughout this entire process, the humidity inside the transfer frame 140 can be confirmed to remain extremely stable, varying within a range of 0.11% to 0.12%.

According to the various embodiments of the present invention as described above, by simultaneously controlling the rotation speed of the FFU and the flow rate supplied through the gas supply unit based on the differential pressure information obtained from the differential pressure sensor, it is possible to effectively suppress the increase in humidity inside the equipment front-end module caused by changes in differential pressure. This, in turn, allows the cleanliness of the substrates to be effectively maintained. It is apparent that the scope of the present invention is not limited by such effects.

While the present invention has been particularly shown and described with reference to embodiments thereof, it will be understood by one of ordinary skill in the art that various changes in form and details may be made therein without departing from the scope of the present invention as defined by the following claims.

What is claimed is:

1. An equipment front-end module comprising:
a load port on which a carriage containing a substrate is seated;
a transfer frame including a space where a substrate contained in the load port is brought in and transferred;
a buffer unit including an open face formed on a surface facing the transfer frame;
a fan filter unit, with one end connected to the other end of a circulation line that is connected to an exhaust port of the buffer unit, configured to introduce gas supplied from the circulation line into the transfer frame;
a gas supply unit configured to supply gas into the transfer frame;
a differential pressure sensor installed on a portion of the transfer frame and configured to measure a differential pressure, which is a value obtained by subtracting an external pressure from an internal pressure of the transfer frame;
a humidity sensor installed on a portion of the transfer frame and configured to measure humidity inside the transfer frame; and
a control unit configured to control a rotation speed of the fan filter unit and a flow rate of gas supplied into the transfer frame through the gas supply unit, based on information received from the humidity sensor and the differential pressure sensor.

2. The equipment front-end module of claim 1, further comprising a fan filter unit control unit configured to receive a fan filter unit control signal transmitted from the control unit and control the rotation speed of the fan filter unit according to the fan filter unit control signal.

3. The equipment front-end module of claim 1, further comprising a mass flow controller configured to receive a gas flow rate control signal transmitted from the control unit and control a flow rate of gas flowing through the gas supply unit according to the gas flow rate control signal.

4. The equipment front-end module of claim 1, wherein the gas supplied into the transfer frame flows into a buffer space through the open face and is discharged through an exhaust port of the buffer unit.

5. The equipment front-end module of claim 1, wherein the control unit is configured to determine whether differential pressure information received from the differential pressure sensor meets preset criteria when it is determined that humidity information received from the humidity sensor deviates from the preset criteria.

6. The equipment front-end module of claim 5, wherein the control unit is configured to perform control to simultaneously increase the rotation speed of the fan filter unit and a flow rate of gas flowing through the gas supply unit when it is determined that the differential pressure information does not meet the preset criteria.

7. The equipment front-end module of claim 5, wherein the control unit is configured to generate a fan filter unit control signal and transmit it to a fan filter unit control unit configured to control the rotation speed of the fan filter unit, while simultaneously generating a gas flow rate control signal and transmitting it to a mass flow controller configured to control the flow rate of gas flowing through the gas supply unit.

8. The equipment front-end module of claim 7, wherein the fan filter unit control signal and the gas flow rate control signal are generated as values proportional to the differential pressure measured by the differential pressure sensor.

9. The equipment front-end module of claim 1, wherein the gas supply unit comprises a gas nozzle configured to discharge gas into an internal space of the transfer frame, a gas supply line connected to the gas nozzle, and a mass flow controller configured to receive a gas flow rate control signal from the control unit and control a flow rate of gas flowing through the gas supply line according to the received gas flow rate control signal.

10. A method for controlling humidity in an equipment front-end module, which comprises a transfer frame including a space where a substrate contained in a load port is brought in and transferred, and a buffer unit with an open face formed on a surface facing the transfer frame, the method comprising:
measuring a differential pressure, which is a value obtained by subtracting an external pressure from an internal pressure of the transfer frame;
comparing the measured differential pressure with a reference value according to preset criteria; and
changing the internal pressure of the transfer frame by changing a flow rate of gas supplied into the transfer frame through a gas supply unit and changing a rotation speed of a fan filter unit configured to supply gas into the transfer frame, when it is determined that the measured differential pressure does not meet the preset criteria.

11. The method of claim 10, further comprising: before measuring the differential pressure,
measuring humidity inside the transfer frame;
comparing the measured humidity with a reference value according to preset criteria; and
determining that the measured humidity does not meet the preset criteria.

12. The method of claim 10, wherein the changing of the flow rate of the supplied gas and the changing of a speed of supply of the gas are performed simultaneously.

13. The method of claim 10, wherein in the comparing of the measured differential pressure with the reference value according to the preset criteria, the preset criteria indicate whether the measured differential pressure has a value less than or greater than the reference value.

14. The method of claim 13, wherein the changing of the flow rate of the supplied gas comprises increasing the flow rate of the supplied gas, and changing of a speed of supply of the gas comprises increasing the speed of supply of the gas supplied.

15. The method of claim 10, further comprising, before measuring the differential pressure, opening the load port to decrease the internal pressure of the transfer frame.

16. The method of claim 15, wherein the changing of the flow rate of the supplied gas is to increase the flow rate of the supplied gas and changing of a speed of supply of the gas is to increase the speed of supply of the supplied gas.

17. The method of claim 10, further comprising, before measuring the differential pressure, closing the load port to increase the internal pressure of the transfer frame.

18. The method of claim 17, wherein the changing of the flow rate of the supplied gas is to reduce the flow rate of the supplied gas, and changing of a speed of supply of the gas is to reduce the speed of supply of the supplied gas.

19. The method of claim 10, wherein the gas supplied into the transfer frame flows into a buffer space through the open face and is discharged through an exhaust port of the buffer unit.

20. An equipment front-end module comprising:
a load port on which a carriage containing a substrate is seated;
a transfer frame including a space where a substrate contained in the load port is brought in and transferred;
a buffer unit including an open face formed on a surface facing the transfer frame and a space where the substrate is temporarily stored;
a fan filter unit, with one end connected to the other end of a circulation line that is connected to an exhaust port of the buffer unit, configured to introduce gas supplied from the circulation line into the transfer frame;
a gas supply unit configured to supply gas into the transfer frame;
a differential pressure sensor configured to measure a pressure difference between the inside and outside of the transfer frame;
a humidity sensor configured to measure humidity inside the transfer frame; and
a control unit configured to control a rotation speed of the fan filter unit and a flow rate of gas supplied through the gas supply unit, based on information received from the humidity sensor and the differential pressure sensor,
wherein the control unit is configured to determine whether differential pressure information received from the differential pressure sensor meets preset criteria when it is determined that humidity information received from the humidity sensor deviates from the preset criteria, and to control the rotation speed of the fan filter unit and the flow rate of gas flowing through the gas supply unit to be changed simultaneously when it is determined that the differential pressure information does not meet the preset criteria.
